(19) United States
(12) Patent Application Publication
(10) Pub. No.: US 2012/0214317 A1
(43) Pub. Date: Aug. 23, 2012

(54) SUBSTRATE PROCESSING APPARATUS AND METHOD, AND SEMICONDUCTOR DEVICE MANUFACTURING METHOD

(75) Inventors: Masaki Murobayashi, Toyama-shi (JP); Takatomo Yamaguchi, Toyama-shi (JP); Kenji Shirako, Toyama-shi (JP); Shuhei Saido, Toyama-shi (JP); Akihiro Sato, Toyama-shi (JP); Yoshinori Imai, Toyama-shi (JP)

(73) Assignee: HITACHI KOKUSAI ELECTRIC INC., Tokyo (JP)

(21) Appl. No.: 13/399,558

(22) Filed: Feb. 17, 2012

(30) Foreign Application Priority Data
Feb. 18, 2011 (JP) 2011-033341

(51) Int. Cl. H01L 21/31; C23C 16/52; C23C 16/455

(52) U.S. Cl. 438/782; 118/724; 257/E21.24

(57) ABSTRACT

A substrate processing apparatus includes a processing chamber configured to process a plurality of substrates, a substrate holder accommodated within the processing chamber and configured to hold the substrates in a vertically spaced-apart relationship, a thermal insulation portion configured to support the substrate holder from below within the processing chamber, a heating unit provided to surround a substrate accommodating region within the processing chamber, and a gas supply system configured to supply a specified gas to at least a thermal insulation portion accommodating region within the processing chamber.

### CROSS-REFERENCE TO RELATED APPLICATIONS

This application is based upon and claims the benefit of priority from Japanese Patent Application No. 2011-033341, filed on Feb. 18, 2011, the entire contents of which are incorporated herein by reference.

### TECHNICAL FIELD

The present disclosure relates to a substrate processing apparatus and method for processing a substrate, and a semiconductor device manufacturing method.

### BACKGROUND

As one example of a material for power devices, attentions is paid to a silicon carbide (SiC) substrate having a silicon carbide (SiC) film formed on the surface thereof. The SiC film can be formed by loading a substrate holder holding a substrate into a processing chamber and supplying a film-forming gas containing silicon elements and a film-forming gas containing carbon elements into the processing chamber while elevating the temperature of the substrate to 1500 to 1800 degrees Celsius by induction heating or the like. In a substrate processing apparatus for performing the film-forming process, a thermal insulation portion is provided below the substrate holder to protect a throat portion having low heat resistance (see, e.g., JP2011-003885A).

The film-formed substrate is unloaded from the processing chamber while reducing the temperature thereof to, e.g., about 500 degrees Celsius. At this time, a cold cooling gas is allowed to flow on the film-formed substrate, thereby accelerating the temperature reduction of the substrate.

### SUMMARY

Through an intensive study, the present inventors have found that, if the thermal insulation portion is provided below the substrate holder, the heat dissipation of the substrate may be hindered and the substrate processing productivity (throughput) may be reduced. The cooling gas supplied to accelerate the temperature reduction makes contact with the substrate and grows hot. The hot gas flows toward the thermal insulation portion, consequently increasing the temperature of the thermal insulation portion. This impedes heat dissipation from the substrate through the thermal insulation portion, increases the time required for reducing the temperature of the substrate and reduces the substrate processing productivity.

In addition, the present inventors have found through an intensive study that, if the thermal insulation portion is provided below the substrate holder, the amount of foreign materials (particles) generated within the processing chamber may be increased and the substrate processing quality may be lowered. Since the temperature of the thermal insulation portion is lower than the temperature of the substrate during the film forming process, it is likely that the film-forming gases and the reaction products flowing toward the thermal insulation portion adhere to the surface of the thermal insulation portion. The adhering materials deposited on the surface of the thermal insulation portion are peeled off, thereby generating particles within the processing chamber and lowering the substrate processing quality.

The present disclosure provides some embodiments of a substrate processing apparatus and a semiconductor device manufacturing method, which are capable of accelerating heat dissipation in the course of reducing the temperature of a substrate and capable of enhancing the substrate processing productivity. Moreover, the present disclosure provides some embodiments of a substrate processing apparatus and a semiconductor device manufacturing method, which are capable of reducing the generation of foreign materials within a processing chamber in a film forming process and capable of increasing the substrate processing quality.

According to one aspect of the present disclosure, there is provided a substrate processing apparatus, including: a processing chamber configured to process a plurality of substrates; a substrate holder accommodated within the processing chamber and configured to hold the substrates in a vertically spaced-apart relationship; a thermal insulation portion configured to support the substrate holder from below within the processing chamber; a heating unit provided to surround a substrate accommodating region within the processing chamber; and a gas supply system configured to supply a specified gas to at least a thermal insulation portion accommodating region within the processing chamber.

According to another aspect of the present disclosure, there is provided a substrate processing apparatus, including: a processing chamber configured to process a plurality of substrates; a substrate holder accommodated within the processing chamber and configured to hold the substrates in a vertically spaced-apart relationship; a thermal insulation portion configured to support the substrate holder from below within the processing chamber; a heating unit provided to surround a substrate accommodating region within the processing chamber; a first gas supply unit configured to supply at least a film-forming gas to the substrate accommodating region within the processing chamber; a second gas supply unit configured to supply at least a cooling gas to a thermal insulation portion accommodating region within the processing chamber; and a control unit configured to control at least the heating unit, the first gas supply unit and the second gas supply unit, the control unit configured to: form specified thin films on the substrates by causing the heating unit to start a heating operation, elevating a temperature of the substrates to a specified temperature and causing the first gas supply unit to start supply of the film-forming gas; and then reduce the temperature of the substrates by stopping the heating operation performed by the heating unit and the supply of the film-forming gas from the first gas supply unit and causing the second gas supply unit to start supply of the cooling gas.

According to a further aspect of the present disclosure, there is provided a substrate processing apparatus, including: a processing chamber configured to process a plurality of substrates; a substrate holder accommodated within the processing chamber and configured to hold the substrates in a vertically spaced-apart relationship; a thermal insulation portion configured to support the substrate holder from below within the processing chamber; a heating unit provided to surround a substrate accommodating region within the processing chamber; a first gas supply unit configured to supply a film-forming gas to the substrate accommodating region within the processing chamber; a second gas supply unit configured to supply at least a film formation inhibiting gas to a thermal insulation portion accommodating region within the processing chamber; and a control unit configured to control at least the heating unit, the first gas supply unit and the second gas supply unit, the control unit configured to form specified thin films on the substrates by causing the heating unit to start a heating operation, elevating a temperature of the substrates to a specified temperature and causing the first gas supply unit to start supply of the film-forming gas, the control unit configured to cause the second gas supply unit to supply the film formation inhibiting gas when forming the thin films.

According to still a further aspect of the present disclosure, there is provided a semiconductor device manufacturing method, including: accommodating a substrate holder and a thermal insulation portion within a processing chamber, the substrate holder configured to hold a plurality of substrates in a vertically spaced-apart relationship, the thermal insulation portion configured to support the substrate holder from below within the processing chamber; forming specified thin films on the substrates by causing a heating unit provided to surround a substrate accommodating region within the processing chamber to start a heating operation, elevating a temperature of the substrates to a specified temperature and causing a first gas supply unit to start supply of a film-forming gas to the substrate accommodating region within the processing chamber; and reducing the temperature of the substrates by stopping the heating operation performed by the heating unit and the supply of the film-forming gas performed by the first gas supply unit and causing a second gas supply unit to start supply of a cooling gas to a thermal insulation portion accommodating region within the processing chamber.

According to yet another aspect of the present disclosure, there is provided a semiconductor device manufacturing method, including: accommodating a substrate holder and a thermal insulation portion within a processing chamber, the substrate holder configured to hold a plurality of substrates in a vertically spaced-apart relationship, the thermal insulation portion configured to support the substrate holder from below within the processing chamber; and forming specified thin films on the substrates by causing a heating unit provided to surround a substrate accommodating region within the processing chamber to start a heating operation, elevating a temperature of the substrates to a specified temperature and causing a first gas supply unit to start supply of a film-forming gas to the substrate accommodating region within the processing chamber, wherein a film formation inhibiting gas is supplied from a second gas supply unit to a thermal insulation portion accommodating region within the processing chamber when forming the thin films.

### BRIEF DESCRIPTION OF THE DRAWINGS

FIG. 1 is a perspective view showing a substrate processing apparatus according to a first embodiment of the present disclosure.

FIG. 2 is a side sectional view showing a processing furnace according to the first embodiment of the present disclosure.

FIG. 3 is a top sectional view of the processing furnace according to the first embodiment of the present disclosure.

FIG. 4 is a block diagram showing a controller according to the first embodiment of the present disclosure.

FIG. 5 is a schematic diagram showing the processing furnace according to the first embodiment of the present disclosure and the surrounding structure thereof.

FIGS. 6A through 6E are schematic views illustrating boat positions when performing substrate processing steps according to the first embodiment of the present disclosure, FIG. 6A showing a boat position before loading the boat, FIG. 6B showing a boat position during temperature elevation and film formation, FIG. 6C showing a boat position during temperature reduction, FIG. 6D showing a boat position during unloading the boat, and FIG. 6E showing a boat position after unloading the boat.

FIG. 7 is a graph representing a gas supply sequence according to the first embodiment of the present disclosure.

FIG. 8A is a side sectional view showing a nozzle of a gas supply unit according to a second embodiment of the present disclosure, and FIG. 8B is a perspective view thereof.

FIG. 9A is a side sectional view showing a nozzle of a gas supply unit according to a third embodiment of the present disclosure, and FIG. 9B is a perspective view thereof.

### DETAILED DESCRIPTION

### First Embodiment

Description will now be made on a first embodiment of the present disclosure.

### (1) Configuration of Substrate Processing Apparatus

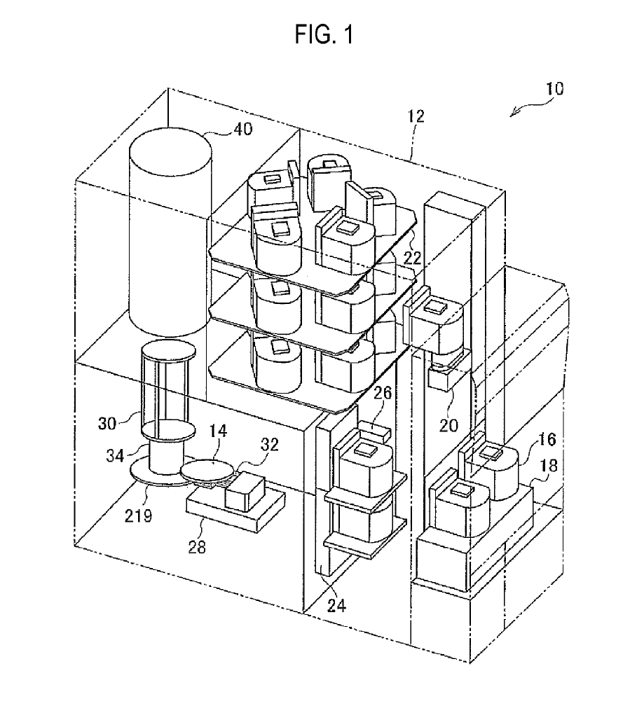

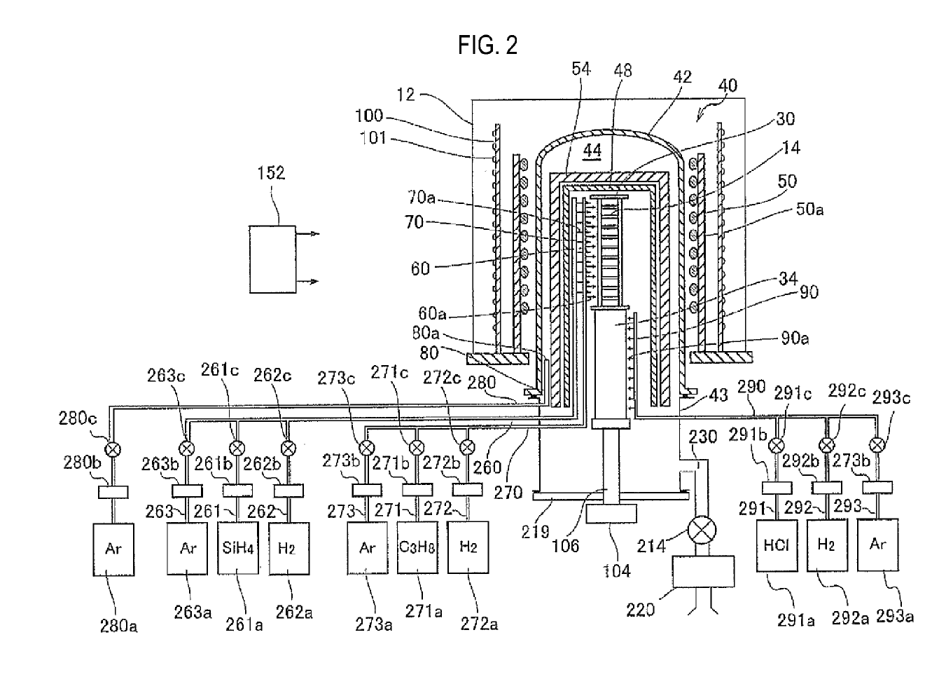

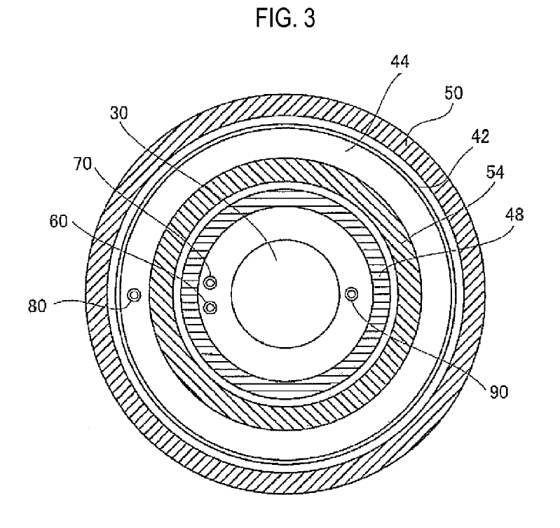

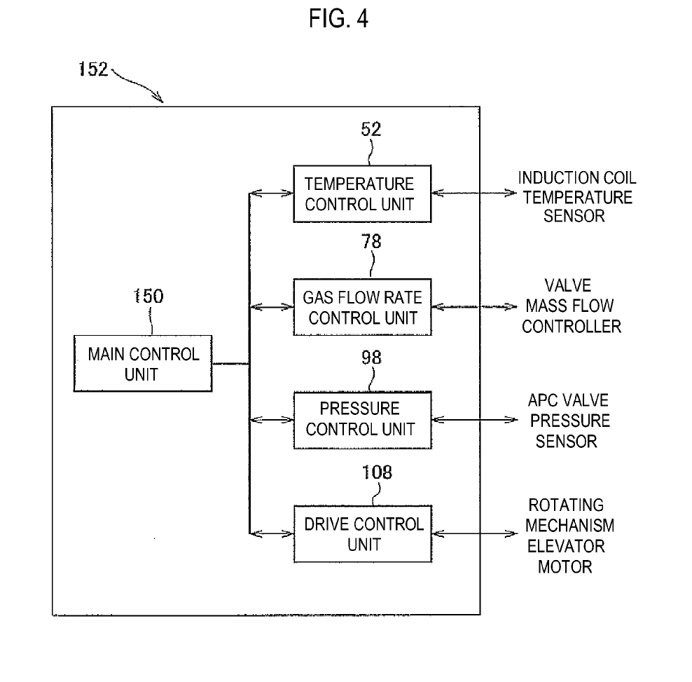

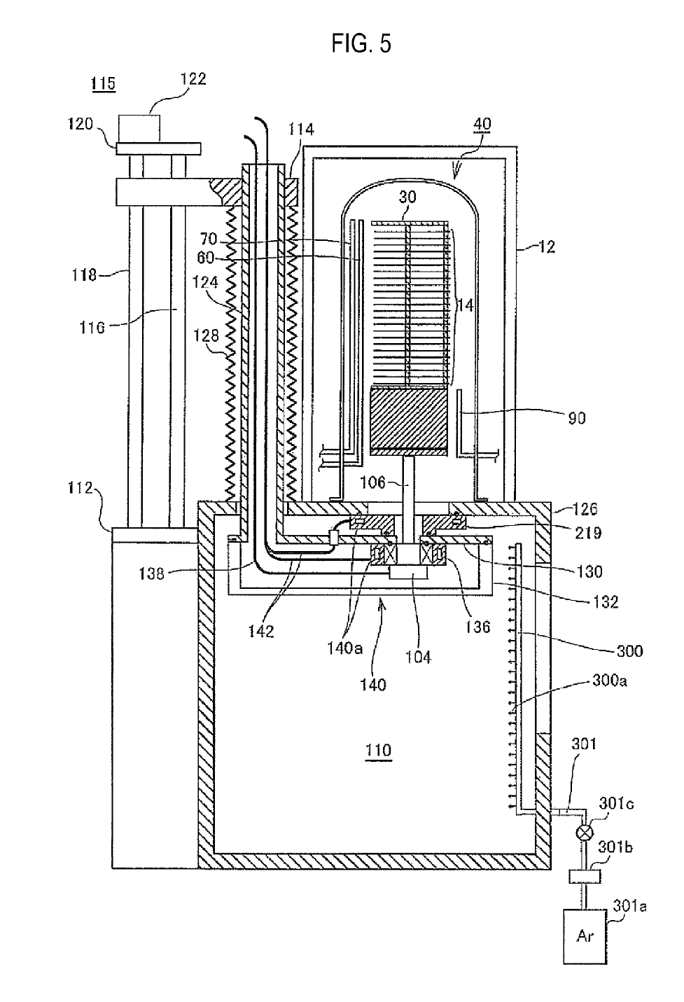

First, the configuration of a substrate processing apparatus 10 according to the present embodiment will be described with reference to FIGS. 1 through 5. FIG. 1 is a perspective view showing a substrate processing apparatus 10 according to the present embodiment. FIG. 2 is a side sectional view showing a processing furnace 40 according to the present embodiment. FIG. 3 is a top sectional view of the processing furnace 40 according to the present embodiment. FIG. 4 is a block diagram showing a controller 152 according to the present embodiment. FIG. 5 is a schematic diagram showing the processing furnace 40 according to the present embodiment and the surrounding structure thereof

### <Overall Configuration>

Referring to FIG. 1, the substrate processing apparatus 10 is a batch-type vertical heat treatment apparatus. The substrate processing apparatus 10 includes a housing 12 in which certain parts such as a processing furnace 40 and the like are provided. A pod 16 is used as a container (wafer carrier) for conveying a substrate into the housing 12. The pod 16 is configured to store a plurality of, e.g., twenty five, wafers 14 as substrates made of Si or SiC. A pod stage 18 is arranged at a front surface side of the housing 12. The pod 16 is configured so that it can be placed on the pod stage 18 with a cover thereof kept closed.

At the front surface side of the housing 12 (at the right side in FIG. 1), a pod conveying device 20 is provided in a position facing the pod stage 18. A pod mounting rack 22, a pod opener 24 and a wafer number detector 26 are provided at the vicinity of the pod conveying device 20. The pod mounting rack 22 is arranged above the pod opener 24 and is configured to hold a plurality of pods 16 mounted thereon. The wafer number detector 26 is provided adjacent to the pod opener 24. The pod conveying device 20 is configured to convey the pod 16 between the pod stage 18, the pod mounting rack 22 and the pod opener 24. The pod opener 24 is configured to open the cover of the pod 16. The wafer number detector 26 is configured to detect the number of the wafers 14 stored within the pod 16 whose cover is opened.

A wafer transfer machine 28 and a boat 30 as a substrate holder are provided within the housing 12. The wafer transfer machine 28 includes an arm (tweezers) 32. The arm 32 can be moved up and down by a drive means not shown in the drawings. The arm 32 is configured to take out, e.g., five wafers, at one time. By operating the arm 32, the wafers 14 can be transferred between the pod 16 placed on the pod opener 24 and the boat 30.

The boat 30 is made of a heat-resistant material, e.g., carbon graphite or SiC. The boat 30 is configured to hold the plurality of wafers 14 which are vertically stacked one above another in a horizontal posture with the centers thereof kept in alignment with each other.

A boat insulation portion 34 as a thermal insulation portion for supporting the boat 30 is provided below the boat 30 (see FIG. 2). The boat insulation portion 34 is made of a heat-resistant material, e.g., quartz (SiO₂) or silicon carbide (SiC), and is formed into, e.g., a hollow cylindrical shape. The boat insulation portion 34 serves as a thermal insulation mechanism that makes it difficult for the heat of the heated boat 30 (the wafers 14) from being transferred to a lower side of the processing furnace 40. An inert gas, e.g., an N₂ gas or Ar gas, as a specified cooling gas (heat exchanging gas) may be supplied into a hollow region of the boat insulation portion 34. The boat insulation portion 34 is not limited to the one set forth above but may be configured by stacking hollow cylindrical members made of, e.g., SiO₂ or SiC, in multiple stages or by stacking disc-shaped insulation plates made of, e.g., SiO₂ or SiC, in multiple stages in a vertical direction.

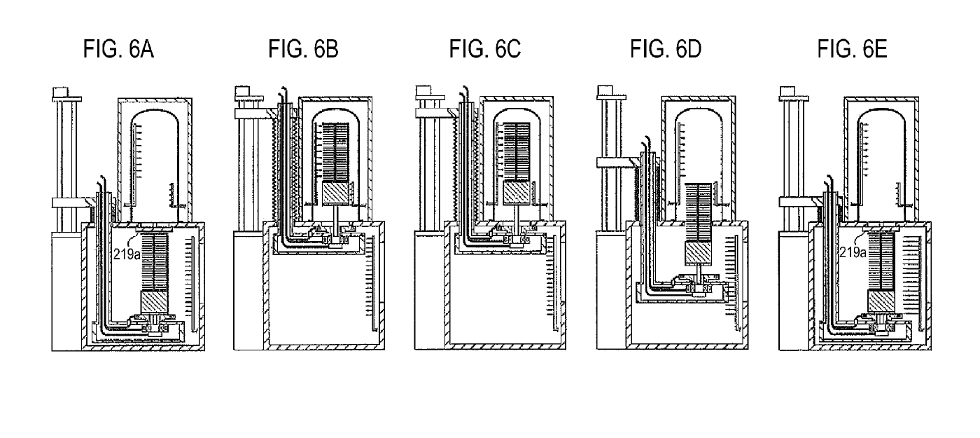

The processing furnace 40 is provided in a rear upper portion within the housing 12. The boat 30 holding the plurality of wafers 14 is loaded into the processing furnace 40 from below. A load lock chamber 110 as a preparatory chamber for receiving the boat 30 and keeping the same in a standby state is provided below the processing furnace 40 (see FIG. 5). The processing furnace 40 has an opening (throat) which can be opened and closed by a throat shutter 219a (see FIG. 6).

### <Configuration of Processing Furnace>

FIGS. 2 and 3 are side and top sectional views showing the processing furnace 40 within which SiC films are formed on the wafers 14.

### (Reaction Vessel)

As shown in FIGS. 2 and 3, the processing furnace 40 includes a reaction tube 42. The reaction tube 42 is made of a heat-resistant material such as quartz or silicon carbide. The reaction tube 42 is formed into a cylindrical shape with a top end thereof closed and a lower end thereof opened. A processing chamber 44 as a reaction chamber is formed in the tubular hollow portion within the reaction tube 42. The processing chamber 44 is configured to accommodate the boat 30 holding the plurality of wafers 14 vertically stacked one above another in a horizontal posture with the centers thereof kept in alignment with each other.

A manifold 43 is provided below the reaction tube 42 in a concentric relationship with the reaction tube 42. The manifold 43 is made of, e.g., stainless steel (SUS). The manifold 43 is formed into a cylindrical shape with upper and lower ends thereof opened. The manifold 43 is configured to support the reaction tube 42 from below. An O-ring as a seal member is provided between the manifold 43 and the reaction tube 42. The manifold 43 is supported by a holder not shown in the drawings, whereby the reaction tube 42 is kept in a vertical posture. A reaction vessel is mainly made up of the reaction tube 42 and the manifold 43.

### (Heating Unit)

The processing furnace 40 includes an inductively heated body 48 heated by induction heating and an induction coil 50 as an induction heating unit (magnetic field generating unit). The inductively heated body 48 is made of an electrically conductive heat-resistant material, e.g., carbon, and is provided to surround the boat 30 accommodated within the processing chamber 44, namely the accommodating region of the wafers 14. The inductively heated body 48 is formed into a cylindrical shape with an upper end thereof closed and a lower end thereof opened. The induction coil 50 is supported by a coil support 50a made of a heat-resistant insulating material and is provided to surround an outer circumference of the reaction tube 42. The induction coil 50 is supplied with an alternating current of, e.g., 10 to 100 kHz and 10 to 200 kW, from an alternating current source not shown in the drawings. If an alternating magnetic field is generated by the alternating current flowing through the induction coil 50, an inductive current (eddy current) flows in the inductively heated body 48. Thus, the inductively heated body 48 is heated by the Joule heat. If the inductively heated body 48 generates heat, the wafers 14 held by the boat 30 and the internal space of the processing chamber 44 are heated to a specified film-forming temperature, e.g., 1500 to 1800 degrees Celsius, by the radiant heat generated from the inductively heated body 48.

A temperature sensor (not shown) for detecting the temperature within the processing chamber 44 is provided at the vicinity of the inductively heated body 48. A below-mentioned temperature control unit 52 (see FIG. 4) is electrically connected to the induction coil 50 and the temperature sensor. The temperature control unit 52 controls the supply of current to the induction coil 50 based on the temperature information detected by the temperature sensor so that the temperature within the processing chamber 44 can have a specified temperature distribution at a specified timing.

A heating unit according to the present embodiment is mainly made up of the inductively heated body 48, the induction coil 50, the coil support 50a, the alternating current source (not shown), the temperature sensor (not shown) and the below-mentioned thermal insulation body 54.

A thermal insulation body 54 is provided between the inductively heated body 48 and the reaction tube 42. The thermal insulation body 54 is made of a material insusceptible to induction heating, e.g., carbon felt. The thermal insulation body 54 is formed into a cylindrical shape with an upper end thereof closed and a lower end thereof opened. Provision of the thermal insulation body 54 makes it possible to restrain the heat of the inductively heated body 48 from being transferred to the reaction tube 42 or the outside of the reaction tube 42.

A shield plate 100 is provided outside the induction coil 50 as an induction heating unit to surround the induction coil 50. The housing 12 is provided outside the shield plate 100 to surround the shield plate 100. The shield plate 100 is made of an electrically conductive material such as Cu (copper). Having the shield plate 100 makes it possible to restrain an inductive current from flowing through an electrically conductive portion of the housing 12 when an alternating current is caused to flow through the induction coil 50.

### (First Gas Supply Unit)

In a sidewall of the manifold 43, a nozzle 60 is provided for supplying a silicon-containing gas as a film-forming gas, a first cooling gas, a third cooling gas and a purge gas to the accommodating region of the wafers 14 and a nozzle 70 is provided for supplying a carbon-containing gas as a film-forming gas, the first cooling gas, the third cooling gas and the purge gas to the accommodating region of the wafers 14. It is possible to use, e.g., a silane (SiH₄) gas as the silicon-containing gas, a propane (C₃H₈) gas as the carbon-containing gas, a hydrogen (H₂) gas as the first cooling gas, and a rare gas, such as an argon (Ar) gas or the like, or a nitrogen (N₂) gas as the third cooling gas and the purge gas.

The nozzles 60 and 70 are formed into a rod-like shape from, e.g., carbon graphite. Downstream extensions of the nozzles 60 and 70 are arranged between the inductively heated body 48 and the expected loading region of the boat 30.

A plurality of gas supply holes 60a, through which the gases are horizontally supplied from one side of the spaces between the wafers 14 stacked (namely, from one side of the accommodating region of the wafers 14), is formed at a side portion of the downstream extension of the nozzle 60. The nozzle 60 supplies the gases to the accommodating region of the wafers 14. However, the nozzle 60 does not directly supply the gases to the boat insulation portion 34 below the accommodating region of the wafers 14. A downstream end of a gas supply pipe 260 is connected to an upstream end of the nozzle 60. A downstream end of a SiH₄ gas supply pipe 261, a downstream end of a H₂ gas supply pipe 262 and a downstream end of an Ar gas supply pipe 263 are connected to an upstream extension of the gas supply pipe 260. A SiH₄ gas supply source 261a, a mass flow controller 261b as a flow rate controller (flow rate control means) and a valve 261c are provided in the SiH₄ gas supply pipe 261 in the named order from the upstream side. A H₂ gas supply source 262a, a mass flow controller 262b as a flow rate controller (flow rate control means) and a valve 262c are provided in the H₂ gas supply pipe 262 in the named order from the upstream side. An Ar gas supply source 263a, a mass flow controller 263b as a flow rate controller (flow rate control means) and a valve 263c are provided in the Ar gas supply pipe 263 in the named order from the upstream side.

A plurality of gas supply holes 70a, through which the gases are horizontally supplied from one side of the spaces between the wafers 14 stacked (namely, from one side of the accommodating region of the wafers 14), is formed at a side portion of the downstream extension of the nozzle 70. The nozzle 70 supplies the gases to the accommodating region of the wafers 14. However, the nozzle 70 does not directly supply the gases to the boat insulation portion 34 below the accommodating region of the wafers 14. A downstream end of a gas supply pipe 270 is connected to the upstream end of the nozzle 70. A downstream end of a C₃H₈ gas supply pipe 271, a downstream end of a H₂ gas supply pipe 272 and a downstream end of an Ar gas supply pipe 273 are connected to an upstream extension of the gas supply pipe 270. A C₃H₈ gas supply source 271a, a mass flow controller 271b as a flow rate controller (flow rate control means) and a valve 271c are provided in the C₃H₈ gas supply pipe 271 in the named order from the upstream side. A H₂ gas supply source 272a, a mass flow controller 272b as a flow rate controller (flow rate control means) and a valve 272c are provided in the H₂ gas supply pipe 272 in the named order from the upstream side. An Ar gas supply source 273a, a mass flow controller 273b as a flow rate controller (flow rate control means) and a valve 273c are provided in the Ar gas supply pipe 273 in the named order from the upstream side.

The valves 261c, 262c, 263c, 271c, 272c and 273c and the mass flow controllers 261b, 262b, 263b, 271b, 272b and 273b are electrically connected to a gas flow rate control unit 78 (see FIG. 4) to be set forth later. The gas flow rate control unit 78 controls the valves 261c, 262c, 263c, 271c, 272c and 273c and the mass flow controllers 261b, 262b, 263b, 271b, 272b and 273b so that the flow rates of the gases supplied into the processing chamber 44 can be equal to specified flow rates at a specified timing.

A first gas supply unit according to the present embodiment is mainly made up of the nozzles 60 and 70, the gas supply holes 60a and 70a, the gas supply pipes 260 and 270, the SiH₄ gas supply pipe 261, the C₃H₈ gas supply pipe 271, the H₂ gas supply pipes 262 and 272, the Ar gas supply pipes 263 and 273, the valves 261c, 262c, 263c, 271c, 272c and 273c, the mass flow controllers 261b, 262b, 263b, 271b, 272b and 273b, the SiH₄ gas supply source 261a, the C₃H₈ gas supply source 271a, H₂ gas supply sources 262a and 272a, and the Ar gas supply sources 263a and 273a. A first nozzle according to the present embodiment is mainly made up of the nozzles 60 and 70.

### (Second Gas Supply Unit)

At least one nozzle 90 as a second nozzle for supplying a film formation inhibiting gas, a second cooling gas, a fourth cooling gas and a purge gas to the accommodating region of the boat insulation portion 34 is provided in the sidewall of the manifold 43. It is possible to use, e.g., a hydrogen chloride (HCL) gas containing chlorine as the film formation inhibiting gas, a hydrogen (H₂) gas as the second cooling gas, and a rare gas, such as an argon (Ar) gas or the like, or a nitrogen (N₂) gas as the fourth cooling gas and the purge gas.

The nozzle 90 is formed into a rod-like shape from, e.g., carbon graphite. A downstream extension of the nozzle 90 is arranged between the inductively heated body 48 and the expected loading region of the boat insulation portion 34. The number of nozzles 90 is not limited to one but may be more than one. In this case, it is preferred that a plurality of nozzles 90 be provided along a circumferential direction of a sidewall of the boat insulation portion 34 at a specified interval.

A plurality of gas supply holes 90a, through which the gases are horizontally supplied from one side of the boat insulation portion 34, is formed at a side portion of the downstream extension of the nozzle 90. The nozzle 90 supplies the gases to the boat insulation portion 34. However, the nozzle 90 does not directly supply the gases to the accommodating region of the wafers 14 above the boat insulation portion 34. A downstream end of a gas supply pipe 290 is connected to an upstream end of the nozzle 90. A downstream end of a HCL gas supply pipe 291, a downstream end of a H₂ gas supply pipe 292 and a downstream end of an Ar gas supply pipe 293 are connected to an upstream extension of the gas supply pipe 290. A HCL gas supply source 291a, a mass flow controller 291b as a flow rate controller (flow rate control means) and a valve 291c are provided in the HCL gas supply pipe 291 in the named order from the upstream side. A H₂ gas supply source 292a, a mass flow controller 292b as a flow rate controller (flow rate control means) and a valve 292c are provided in the H₂ gas supply pipe 292 in the named order from the upstream side. An Ar gas supply source 293a, a mass flow controller 293b as a flow rate controller (flow rate control means) and a valve 293c are provided in the Ar gas supply pipe 293 in the named order from the upstream side.

The valves 291c, 292c and 293c and the mass flow controllers 291b, 292b and 293b are electrically connected to the gas flow rate control unit 78 (see FIG. 4) to be set forth later. The gas flow rate control unit 78 controls the valves 291c, 292c and 293c and the mass flow controllers 291b, 292b and 293b so that the flow rates of the gases supplied into the processing chamber 44 can be equal to specified flow rates at a specified timing.

A second gas supply unit according to the present embodiment is made up of the valve 90, the gas supply holes 90a, the gas supply pipe 290, the HCL gas supply pipe 291, the H₂ gas supply pipe 292, the Ar gas supply pipe 293, the valves 291c, 292c and 293c, the mass flow controllers 291b, 292b and 293b, the HCL gas supply source 291a, the H₂ gas supply source 292a and the Ar gas supply source 293a.

### (Purge Gas Supply Unit)

A nozzle 80 for supplying a purge gas to a space between the reaction tube 42 and the thermal insulation body 54 is provided in the sidewall of the manifold 43. It is possible to use, e.g., a rare gas, such as an argon (Ar) gas or the like, or a nitrogen (N₂) gas as the purge gas.

The nozzle 80 is formed into a rod-like shape from, e.g., carbon graphite. A downstream extension of the nozzle 80 is arranged between the reaction tube 42 and the thermal insulation body 54. At least one gas supply hole 80a is formed at the downstream extension of the nozzle 80. A downstream end of the gas supply pipe 280 is connected to an upstream end of the nozzle 80. An Ar gas supply source 281a, a mass flow controller 281b as a flow rate controller (flow rate control means) and a valve 281c are provided in the gas supply pipe 280 in the named order from the upstream side. The valve 280c and the mass flow controller 280b are electrically connected to the gas flow rate control unit 78 (see FIG. 4) to be set forth later. The gas flow rate control unit 78 controls the valve 280c and the mass flow controller 280b so that the flow rates of the gases supplied into the processing chamber 44 can be equal to specified flow rates at a specified timing.

A purge gas supply system is mainly made up of the nozzle 80, the gas supply hole 80a, the gas supply pipe 280, the valve 280c, the mass flow controller 280b and the Ar gas supply source 280a.

### (Exhaust System)

An upstream end of an exhaust pipe 230 through which to discharge an atmospheric gas existing within the processing chamber 44 is connected to a lower portion of the sidewall of the manifold 43. A pressure sensor not shown in the drawings, an APC (Auto Pressure Controller) valve 214 as a pressure regulating device, and a vacuum pump 220 are provided in the exhaust pipe 230 in the named order from the upstream side. The pressure sensor (not shown), the APC valve 214 and the vacuum pump 220 are electrically connected to a pressure control unit 98 (see FIG. 4) to be set forth below. The pressure control unit 98 feedback controls the opening degree of the APC valve 214 based on the pressure information measured by the pressure sensor so that the pressure within the processing chamber 44 can be equal to a specified pressure at a specified timing.

An exhaust system according to the present embodiment is mainly made up of the exhaust pipe 230, the pressure sensor (not shown), the APC valve 214 and the vacuum pump 220.

With the configuration described above, the film-forming gases (the silicon-containing gas and the carbon-containing gas), the first cooling gas and the third cooling gas supplied from the first gas supply unit are caused to flow parallel to the surfaces of the wafers 14 and then flow downward within the processing chamber 44 along the sidewall of the boat insulation portion 34. Thereafter, the gases are discharged from the exhaust pipe 230.

The purge gas supplied from the purge gas supply unit is caused to flow between the reaction tube 42 and the thermal insulation body 54 and is discharged from the exhaust pipe 230.

### <Surrounding Structure of Processing Furnace>

Next, description will be made on the surrounding structure of the processing furnace 40. FIG. 5 is a schematic diagram showing the processing furnace 40 according to the first embodiment of the present disclosure and the surrounding structure thereof.

As stated above, the load lock chamber 110 as a preparatory chamber is provided below the processing furnace 40. In the load lock chamber 110, there are provided a third gas supply unit for supplying a fifth cooling gas into the load lock chamber 110 and a boat elevator for conveying the boat 30 between the inside of the processing furnace 40 and the inside of the load lock chamber 110. The inside of the load lock chamber 110 is evacuated by an exhaust system not shown in the drawings.

### (Third Gas Supply System)

A nozzle 300 for supplying a fifth cooling gas and a purge gas to the accommodating region of the wafers 14 within the load lock chamber 110 is provided at a sidewall of the load lock chamber 110. It is possible to use, e.g., a rare gas, such as an argon (Ar) gas or the like, or a nitrogen (N₂) gas as the fifth cooling gas and the purge gas.

The nozzle 300 is formed into a rod-like shape from, e.g., carbon graphite. The number of nozzles 300 is not limited to one but may be more than one. In this case, it is preferred that a plurality of nozzles 300 be provided along the circumferential direction of the sidewalls of the boat 30 and the boat insulation portion 34 at a specified interval.

A plurality of gas supply holes 300a, through which the gases are horizontally supplied from one side of the accommodating region of the wafers 14, is formed at a side portion of a downstream extension of the nozzle 300. The nozzle 300 is configured to supply the gases to not only the accommodating region of the wafers 14 but also the boat insulation portion 34 below the accommodating region of the wafers 14. A downstream end of a gas supply pipe 301 is connected to an upstream end of the nozzle 300. An Ar gas supply source 301a, a mass flow controller 301b as a flow rate controller (flow rate control means) and a valve 301c are provided in the gas supply pipe 301 in the named order from the upstream side.

The valve 301c and the mass flow controller 301b are electrically connected to the gas flow rate control unit 78 (see FIG. 4) to be set forth later. The gas flow rate control unit 78 controls the valve 301c and the mass flow controller 301b so that the flow rate of the gas supplied into the load lock chamber 110 can be equal to a specified flow rate at a specified timing.

A third gas supply unit according to the present embodiment is made up of the nozzle 300, the gas supply holes 300a, the gas supply pipe 301, the valve 301c, the mass flow controller 301b and the Ar gas supply source 301a.

A gas supply system according to the present embodiment is made up of: the first gas supply unit, the second gas supply unit and the purge gas supply unit for supplying the gases into the processing chamber 44; and the third gas supply unit for supplying the gas into the load lock chamber 110.

### (Boat Elevator)

A boat elevator 115 is provided on an outer surface of the sidewall of the load lock chamber 110. The boat elevator 115 includes a lower base plate 112, a guide shaft 116, a ball screw 118, an upper base plate 120, an elevator motor 122, an elevator base plate 130 and bellows 128. The lower base plate 112 is fixed to the outer surface of the sidewall of the load lock chamber 110 in a horizontal posture. The guide shaft 116 fitted to an elevator table 114 and the ball screw 118 threadedly engaging the elevator table 114 are installed on the lower base plate 112 in a vertical posture. The upper base plate 120 is fixed to upper ends of the guide shaft 116 and the ball screw 118 in a horizontal posture. The ball screw 118 is rotated by the elevator motor 122 mounted to the upper base plate 120. The guide shaft 116 allows the elevator table 114 to move up and down while restraining the elevator table 114 from rotating in the horizontal direction. The elevator table 114 is moved up and down by rotating the ball screw 118.

A hollow elevator shaft 124 is fixed to the elevator table 114 in a vertical posture. The connecting portion of the elevator table 114 and the elevator shaft 124 is kept air-tight. The elevator shaft 124 is moved up and down together with the elevator table 114. A lower end portion of the elevator shaft 124 extends through the top plate 126 of the load lock chamber 110. An inner diameter of a through-hole formed in the top plate 126 of the load lock chamber 110 is set greater than an outer diameter of the elevator shaft 124 to prevent the elevator shaft 124 and the top plate 126 from making contact with each other. The bellows 128 as a hollow expansion and contraction body having flexibility is provided between the load lock chamber 110 and the elevator table 114 to surround an outer circumference of the elevator shaft 124. The connecting portion of the elevator table 114 and the bellows 128 and the connecting portion of the top plate 126 and the bellows 128 are kept air-tight, thereby hermetically sealing the inside of the load lock chamber 110. The bellows 128 is flexible enough to permit the up-and-down movement of the elevator table 114. An inner diameter of the bellows 128 is sufficiently larger than the outer diameter of the elevator shaft 124 so that the elevator shaft 124 and the bellows 128 do not make contact with each other.

The elevator base plate 130 is horizontally fixed to a lower end of the elevator shaft 124 protruding into the load lock chamber 110. The connecting portion of the elevator shaft 124 and the elevator base plate 130 is kept air-tight. A seal cap 219 is air-tightly attached to an upper surface of the elevator base plate 130 through a seal member such as an O-ring. The seal cap 219 is formed into a disc shape from metal, e.g., stainless steel. If the elevator table 114, the elevator shaft 124, the elevator base plate 130 and the seal cap 219 are moved up by driving the elevator motor 122 and rotating the ball screw 118, the boat 30 is loaded into the processing chamber 44 (boat loading) and the opening (throat) of the processing furnace 40 is closed by the seal cap 219. If the elevator table 114, the elevator shaft 124, the elevator base plate 130 and the seal cap 219 are moved down by driving the elevator motor 122 and rotating the ball screw 118, the boat 30 is unloaded from the processing chamber 44 (boat unloading). A drive control unit 108 is electrically connected to the elevator motor 122. The drive control unit 108 controls the boat elevator 115 to perform specified operations at specified timings.

### (Rotating Mechanism)

A drive unit cover 132 is air-tightly attached to a lower surface of the elevator base plate 130 through a seal member such as an O-ring. The elevator base plate 130 and the drive unit cover 132 make up a drive unit storage case 140. The inside of the drive unit storage case 140 is isolated from the atmosphere within the load lock chamber 110. A rotating mechanism 104 is provided within the drive unit storage case 140. A power supply cable 138 is connected to the rotating mechanism 104. The power supply cable 138 extends from an upper end of the elevator shaft 124 to the rotating mechanism 104 through the elevator shaft 124 so that an electric current can be supplied to the rotating mechanism 104 via the power supply cable 138. The rotating mechanism 104 includes a rotating shaft 106, an upper end portion of which extends through the seal cap 219 to support the boat 30 from below. By operating the rotating mechanism 104, the wafers 14 held in the boat 30 can be rotated within the processing chamber 44. The drive control unit 108 is electrically connected to the rotating mechanism 104. The drive control unit 108 controls the rotating mechanism 104 so that the rotating mechanism 104 can perform specified operations at specified timings.

A cooling mechanism 136 is provided around the rotating mechanism 104 within the drive unit storage case 140. Cooling flow paths 140a are formed in the cooling mechanism 136 and the seal cap 219. Cooling water pipes 142 through which to supply cooling water are connected to the cooling flow paths 140a. The cooling water pipes 142 extend from the upper end of the elevator shaft 124 to the cooling flow paths 140a through the elevator shaft 124 so that the cooling water can be supplied to the cooling flow paths 140a via the cooling water pipes 142.

### <Controller>

FIG. 4 is a block diagram showing a controller 152 as a control unit for controlling the operations of the respective parts of the substrate processing apparatus 10. The controller 152 includes a main control unit 150, the temperature control unit 52, the gas flow rate control unit 78, the pressure control unit 98 and the drive control unit 108, the later four of which are electrically connected to the main control unit 150. The main control unit 150 includes an operation part and an input/output part.

The controller 152 is configured to: elevate the temperature of the wafers 14 to, e.g., 1500 to 1800 degrees Celsius, by causing the induction coil 50 to start induction heating of the inductively heated body 48; form SiC films on the wafers 14 by causing the first gas supply unit to start the supply of film-forming gases (e.g., a SiH₄ gas and a C₃H₈ gas); cause the induction coil 50 to stop the induction heating of the inductively heated body 48 while causing the first gas supply unit to stop the supply of the film-forming gases; and reduce the temperature of the wafers 14 by causing the second gas supply unit to start the supply of a first cooling gas (e.g., a H₂ gas). These control operations will be described later.

The controller 152 is configured to cause the second gas supply unit to supply a film formation inhibiting gas (e.g., an HCL gas), when increasing the temperature of the wafers 14 to, e.g., 1500 to 1800 degrees Celsius, by causing the induction coil 50 to start induction heating of the inductively heated body 48 and when forming the SiC films on the wafers 14 by causing the first gas supply unit to start the supply of the film-forming gases (e.g., the SiH₄ gas and the C₃H₈ gas). These control operations will also be described later.

### (2) Substrate Processing Steps

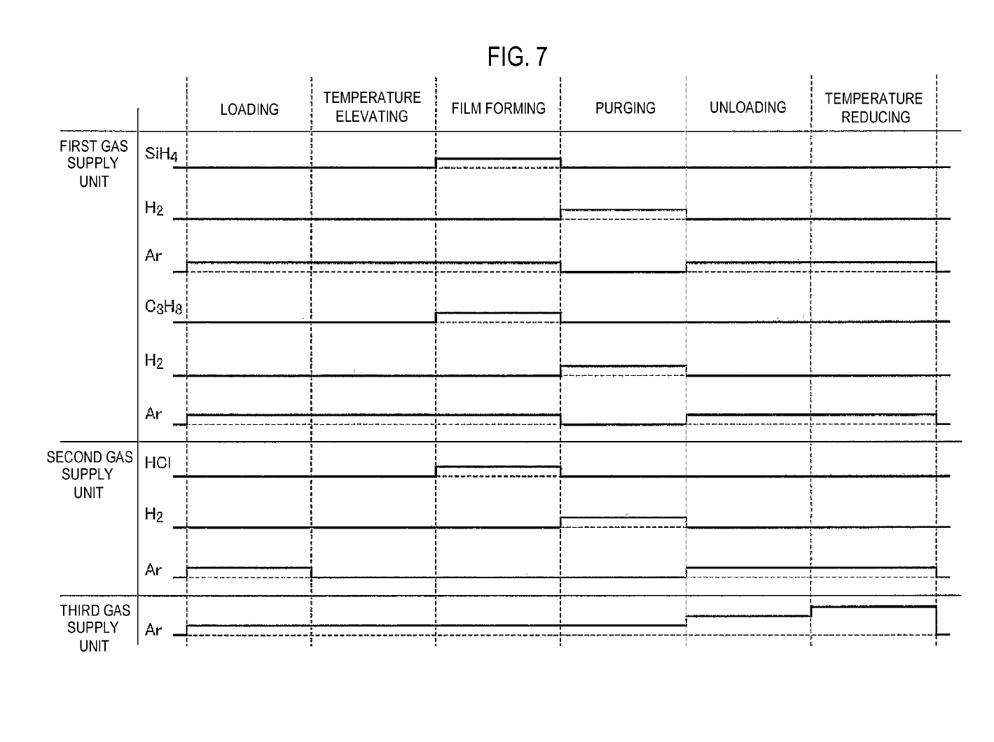

Next, as one example of semiconductor device manufacturing steps, substrate processing steps for forming, e.g., SiC films, on the wafers 14 will be described with reference to FIGS. 6 and 7. FIGS. 6A through 6E are schematic views illustrating boat positions when performing substrate processing steps according to the present embodiment, FIG. 6A showing a boat position before loading the boat, FIG. 6B showing a boat position during temperature elevation and film formation, FIG. 6C showing a boat position during temperature reduction, FIG. 6D showing a boat position during unloading the boat, and FIG. 6E showing a boat position after unloading the boat. FIG. 7 is a graph representing a gas supply sequence according to the present embodiment. The substrate processing steps are performed by the substrate processing apparatus 10 described above. In the following description, the operations of the respective parts making up the substrate processing apparatus 10 are controlled by the controller 152.

### (Loading Step)

The pod 16 containing the plurality of wafers 14 is placed on the pod stage 18 and then transferred to the pod mounting rack 22 by the pod conveying device 20. The pod 16 placed on the pod mounting rack 22 is conveyed to the pod opener 24 by the pod conveying device 20. The cover of the pod 16 is opened by the pod opener 24. The number of the wafers 14 contained in the pod 16 is detected by the wafer number detector 26. The wafers 14 are taken out from the pod 16 and transferred to the boat 30 within the load lock chamber 110 by the wafer transfer machine 28. FIG. 6A illustrates a state in which the wafers 14 are completely charged to the boat 30.

During the course of charging the wafers 14, an Ar gas as a purge gas is supplied from the third gas supply unit, thereby purging the load lock chamber 110. In other words, while evacuating the inside of the load lock chamber 110 by use of the exhaust system not shown in the drawings, the valve 301c is opened and the Ar gas whose flow rate is regulated by the mass flow controller 301b is supplied into the load lock chamber 110, thereby purging the load lock chamber 110. This makes it possible to restrain particles from adhering to the wafers 14. At this time, the throat shutter 219a is closed and the opening (throat) of the processing furnace 40 is kept air-tight. The supply of the purge gas from the third gas supply unit is continuously performed at least until the temperature reducing step to be described later comes to an end.

After the wafers 14 are completely charged into the boat 30, the throat shutter 219a is opened and the boat elevator 115 is operated to load the boat 30 into the processing chamber 44 (boat loading). After the boat 30 is completely loaded, the lower end of the manifold 43 is hermetically sealed by the seal cap 219. FIG. 6B illustrates a state in which the boat 30 is completely loaded.

During the course of loading the boat 30, an Ar gas as a purge gas is supplied from the first gas supply unit and the second gas supply unit while continuously supplying the Ar gas from the third gas supply unit, thereby purging the processing chamber 44. More specifically, while evacuating the processing chamber 44 by operating the vacuum pump 220 and opening the APC valve 214 in that state, the valves 263c, 273c, 280c and 293c are further opened and the Ar gas whose flow rate is regulated by the mass flow controllers 263b, 273b, 280b and 293b is supplied into the processing chamber 44, thereby purging the processing chamber 44. In order to prevent particles from diffusing (swirling) into the processing chamber 44 from the load lock chamber 110, it is preferred in the loading step that the flow rate of the Ar gas supplied into the processing chamber 44 be set greater than the flow rate of the Ar gas supplied into the load lock chamber 110, eventually generating a gas stream flowing from the processing chamber 44 toward the load lock chamber 110.

### (Pressure Reducing and Temperature Elevating Step)

After the boat 30 is completely loaded into the processing chamber 44, the opening degree of the APC valve 214 is feedback controlled pursuant to the pressure information measured by the pressure sensor, thereby evacuating the processing chamber 44 so that the internal pressure of the processing chamber 44 can be equal to a specified pressure (vacuum degree). At this time, the supply of the Ar gas into the processing chamber 44 may be continuously performed or stopped. FIG. 7 illustrates, by way of example, a case where the supply of the Ar gas from the second gas supply unit is stopped while continuously performing the supply of the Ar gas from the first gas supply unit.

An alternating current of, e.g., 10 to 100 kHz and 10 to 200 kW, is supplied from the alternating current source (not shown) to the induction coil 50. Thus, an alternating magnetic field is applied to the inductively heated body 48 and an inductive current is allowed to flow through the inductively heated body 48, thereby causing the inductively heated body 48 to generate heat. The wafers 14 held in the boat 30 and the inside of the processing chamber 44 are heated to a film-forming temperature of, e.g., 1500 to 1800 degrees Celsius, by the radiant heat generated from the inductively heated body 48. At this time, the temperature of the wafers 14 and the temperature within the processing chamber 44 can be adjusted by feedback controlling the supply of the current to the induction coil 50 pursuant to the temperature information detected by the temperature sensor.

When supplying the electric current to the induction coil 50 and heating the wafers 14, the rotating mechanism 104 is operated to rotate the boat 30 and the wafers 14. The rotation of the boat 30 and the wafers 14 is continuously performed at least until the film forming step to be described later comes to an end.

### (Film Forming Step)

If the temperature of the wafers 14 and the inside of the processing chamber 44 reaches a specified film-forming temperature (1500 to 1800 degrees Celsius), the valves 261c and 271c are opened to start the supply of a SiH₄ gas and a C₃H₈ gas as film-forming gases into the processing chamber 44. The SiH₄ gas and the C₃H₈ gas supplied into the processing chamber 44 flow in parallel to the surfaces of the wafers 14 held in the boat 30. SiC films are formed on the wafers 14 as the SiH₄ gas and the C₃H₈ gas make contact with the surfaces of the hot wafers 14.

At this time, it is preferred in this embodiment that the valves 263c and 273c be kept opened and the supply of the Ar gas from the first gas supply unit be continuously performed. The Ar gas supplied from the first gas supply unit serves as a carrier gas for urging the SiH₄ gas and the C₃H₈ gas to be supplied or diffused into the processing chamber 44 more rapidly. At this time, it is also preferred that the valve 280c be opened to start the supply of an Ar gas as a purge gas from the purge gas supply unit. This makes it possible to restrain the film-forming gases from infiltrating into a space between the reaction tube 42 and the thermal insulation body 54 and to restrain unnecessary byproducts from adhering to the surfaces of the reaction tube 42 and the thermal insulation body 54.

As stated above, the boat 30 holding the wafers 14 is supported by the boat insulation portion 34 from below. The boat insulation portion 34 is formed into, e.g., a hollow cylindrical shape, from a heat-resistant material such as quartz or silicon carbide. Therefore, the film-forming gases heated to a high temperature make contact with the sidewall of the boat insulation portion 34 and exchange heat with the boat insulation portion 34, whereby the boat insulation portion 34 serves to reduce the temperature of the film-forming gases heated to a high temperature. The boat insulation portion 34 serves as a thermal insulation mechanism that makes it hard for the heat of the boat 30 (the wafers 14) heated by the inductively heated body 48 from being transferred to the lower side of the processing furnace 40. By allowing the boat insulation portion 34 to serve as a heat exchange mechanism or a thermal insulation mechanism, it is possible to reduce thermal damage to the component members positioned below the processing furnace 40 (e.g., the manifold 43, the seal cap 219, the rotating mechanism 104, the load lock chamber 110, etc.).

However, the present inventors have found through an intensive study that, if the boat insulation portion 34 is provided below the boat 30, the amount of foreign materials (particles) generated within the processing chamber 44 may be increased and the substrate processing quality may be lowered. The temperature of the boat insulation portion 34 serving as a thermal insulation mechanism becomes lower than the temperature of the wafers 14 and the boat 30 (e.g., 1500 to 1800 degrees Celsius). More specifically, the temperature of the sidewall of the boat insulation portion 34 becomes gradually lower from the accommodating region of the wafers 14 toward the lower side of the processing furnace 40. The film-forming gases not consumed on the surfaces of the wafers 14 and the reaction products generated by the film forming reaction flow toward the lower side of the processing chamber 44 along the sidewall of the boat insulation portion 34. Since the temperature of the sidewall of the boat insulation portion 34 is kept low as mentioned above, the film-forming gases and the reaction products easily adhere to the sidewall of the boat insulation portion 34. The adhering materials deposited on the sidewall of the boat insulation portion 34 are peeled off, thereby generating particles within the processing chamber 44. An adhesive force is usually weak in the above case, and thus the adhering materials are easily peeled off by the change in pressure and temperature.

In the present embodiment, a film formation inhibiting gas is supplied from the second gas supply unit when forming the SiC films on the wafers 14, thereby preventing the film-forming gases and the reaction products from adhering to the boat insulation portion 34. In other words, when opening the valves 261c and 271c and supplying the SiH₄ gas and the C₃H₈ gas to the accommodating region of the wafers 14, the valve 291c is also opened so that a HCL gas as a film formation inhibiting gas can flow in the accommodating region of the boat insulation portion 34. Therefore, even if the temperature of the sidewall of the boat insulation portion 34 is lower than the afore-mentioned film-forming temperature (e.g., 1500 to 1800 degrees Celsius), it is possible to effectively restrain the film-forming gases and the reaction products from adhering to the surface of the boat insulation portion 34 and to reduce the amount of particles generated within the processing chamber 44.

The pressure within the processing chamber 44 (the processing pressure) in the film forming step is set to fall within a range of, e.g., from 1330 to 13300 Pa. The flow rate of the SiH₄ gas controlled by the mass flow controller 261b is set to fall within a range of, e.g., from 100 to 300 sccm. The flow rate of the C₃H₈ gas controlled by the mass flow controller 271b is set to fall within a range of, e.g., from 10 to 100 sccm. The flow rate of the HCL gas controlled by the mass flow controller 291b is set to fall within a range of, e.g., from 100 to 1000 sccm.

If the SiC films having a specified thickness are formed after a lapse of a specified time period, the valves 261c and 271c are closed and the supply of the SiH₄ gas and the C₃H₈ gas to the accommodating region of the wafers 14 is stopped. The valve 291c is closed and the supply of the HCL gas to the accommodating region of the boat insulation portion 34 is stopped. The supply of the alternating current to the induction coil 50 is stopped and the induction heating of the inductively heated body 48 is stopped.

### (Temperature Reducing and Atmospheric Pressure Restoring Step)

After stopping the supply of the film-forming gases to the accommodating region of the wafers 14, the supply of the HCL gas to the accommodating region of the boat insulation portion 34 and the supply of the alternating current to the induction coil 50, the boat 30 is kept in a standby state until the temperature of the wafers 14 is reduced from the just-after-processing temperature (e.g., 1500 to 1800 degrees Celsius) to a specified conveying temperature (e.g., 500 to 800 degrees Celsius which is the heat resistance temperature of the load lock chamber 110). FIG. 6C illustrates a state in which the boat 30 is kept in the standby state within the processing chamber 44. The temperature reduction of the wafers 14 is gradually performed by the heat transfer from the boat 30 through the boat insulation portion 34. At this time, a H₂ gas as a first cooling gas is supplied from the first gas supply unit, which makes it possible to accelerate the cooling of the wafers 14. In other words, while evacuating the inside of the processing chamber 44, the valves 262c and 272c are opened and the H₂ gas having an increased heat exchange rate is allowed to flow toward the surfaces of the wafers 14. This makes it possible to accelerate heat exchange between the wafers 14 and the H₂ gas and to reduce the temperature of the wafers 14 more rapidly.

However, the present inventors have found through an intensive study that, if the boat insulation portion 34 is provided below the boat 30, the heat dissipation of the wafers 14 may be hindered and the time required for the temperature reducing step may be longer, which may reduce the substrate processing productivity. The H₂ gas as a first cooling gas supplied to accelerate the temperature reduction becomes hot by making contact with, and exchanging heat with, the wafers 14. The hot H₂ gas flows toward the boat insulation portion 34 and increases the temperature of the boat insulation portion 34. As a result, the heat transfer through the boat insulation portion 34 is hindered and the wafers 14 are reheated by the radiant heat from the boat insulation portion 34. For example, if the boat insulation portion 34 is provided below the boat 30, an extended time period as long as 100 to 150 minutes is required for reducing the temperature of the wafers 14 to the conveying temperature (e.g., 500 to 800 degrees Celsius).

In the present embodiment, when reducing the temperature of the wafers 14, namely when supplying the H₂ gas as a first cooling gas to the wafers 14, a H₂ gas as a second cooling gas is also supplied from the second gas supply unit, thereby preventing the temperature from rising in the boat insulation portion 34. In other words, while evacuating the inside of the processing chamber 44, the valves 262c and 272c are opened and the valve 292c is also opened so that the H₂ gas as a second cooling gas can flow toward the sidewall of the boat insulation portion 34. Therefore, even if the H₂ gas grown hot by the heat exchange with the wafers 14 flows along the sidewall of the boat insulation portion 34, it is possible to effectively prevent the temperature from rising in the boat insulation portion 34. As a consequence, it is possible to shorten the time required for the temperature reducing step and to improve the substrate processing productivity.

The pressure within the processing chamber 44 during temperature reduction is set to fall within a range of, e.g., from 1000 to 3000 Pa. The flow rate of the H₂ gas controlled by the mass flow controller 262b is set to fall within a range of, e.g., from 3000 to 10000 sccm. The flow rate of the H₂ gas controlled by the mass flow controller 272b is set to fall within a range of, e.g., from 3000 to 10000 sccm. The flow rate of the H₂ gas controlled by the mass flow controller 292b is set to fall within a range of, e.g., from 10000 to 100000 sccm.

If the temperature of the wafers 14 and the boat 30 is reduced to a specified boat unloading temperature (e.g., 500 to 800 degrees Celsius) after lapse of a specified time period, the valves 262c and 272c are closed to stop the supply of the H₂ gas into the processing chamber 44 and the valves 263c and 273c are opened to start the supply of the Ar gas as a third cooling gas into the processing chamber 44. Simultaneously, the valve 292c is closed to stop the supply of the H₂ gas to the sidewall of the boat insulation portion 34 and the valve 293c is opened to start the supply of the Ar gas as a fourth cooling gas into the processing chamber 44. Moreover, the valve 280c is opened to start the supply of the Ar gas as a purge gas into the processing chamber 44. Thereafter, the opening degree of the APC valve 214 is adjusted so that the pressure within the processing chamber 44 can be restored to the atmospheric pressure.

### (Unloading Step)

After the inside of the processing chamber 44 is purged by the Ar gas and after the pressure within the processing chamber 44 is restored to the atmospheric pressure, the boat elevator 115 is operated to start the unloading of the boat 30 from the inside of the processing chamber 44. FIG. 6D illustrates a state in which the boat 30 is being unloaded.

During the course of unloading the boat 30, the supply of the Ar gas as a fifth cooling gas from the third gas supply unit is started while continuously performing the supply of the Ar gas (the third cooling gas, the fourth cooling gas and the purge gas) into the processing chamber 44, thereby continuously cooling the wafers 14 being conveyed. In order to accelerate the cooling of the wafers 14 within the load lock chamber 110, it is preferred in some embodiments that the flow rate of the Ar gas (the fifth cooling gas) supplied from the third gas supply unit in the unloading step be set to be greater than the flow rate of the Ar gas (the purge gas) supplied from the third gas supply unit in the loading step through the temperature reducing step. With a view to prevent particles from diffusing into the processing chamber 44 from the inside of the load lock chamber 110, it is preferred in some embodiments that, in the unloading step, the flow rate of the Ar gas supplied into the load lock chamber 110 be set to be smaller than the flow rate of the Ar gas supplied into the processing chamber 44.

### (Post-Unloading Cooling Step)

After unloading the boat 30, the throat shutter 219a is closed to hermetically seal the inside of the processing chamber 44 (the opening of the processing furnace 40). FIG. 6E illustrates a state in which the boat 30 is completely unloaded. Then, a standby state lasts until the temperature of the wafers 14 is reduced from the boat unloading temperature (e.g., 500 to 800 degrees Celsius) to a specified wafer conveying temperature (e.g., the normal temperature to 80 degrees Celsius). At this time, the cooling of the wafers 14 can be accelerated by continuously supplying the Ar gas as a fifth cooling gas from the third gas supply unit. Since the throat shutter 219a is kept closed at this time, the flow rate of the Ar gas supplied into the load lock chamber 110 can be made greater than the flow rate thereof in the unloading step. This makes it possible to further accelerate the cooling of the wafers 14.

After the temperature of the wafers 14 is reduced to a specified wafer conveying temperature (e.g., 80 degrees Celsius), the supply of the Ar gas into the load lock chamber 110 is stopped. The temperature-reduced wafers 14 are taken out from the boat 30 and received within an empty pod 16 in the order opposite to the afore-mentioned order. The wafers 14 are conveyed to another substrate processing apparatus for performing other substrate processing steps. Thus, the substrate processing steps of the present embodiment comes to an end.

### (3) Effects Provided by the Present Embodiment

The present embodiment provides one or more effects set forth below.

(a) With the present embodiment, there is provided the boat insulation portion 34 for supporting the boat 30 from below. The boat insulation portion 34 is made of a heat-resistant material, e.g., quartz (SiO₂) or silicon carbide (SiC), and is formed into, e.g., a hollow cylindrical shape. Thus, the boat insulation portion 34 serves as a thermal insulation mechanism that makes it difficult for heat of the boat 30 (the wafers 14) heated by the induced body 48 from being transferred to the lower side of the processing furnace 40. By allowing the boat insulation portion 34 to serve as a thermal insulation mechanism, it is possible to reduce thermal damage to the component members positioned below the processing furnace 40 (e.g., the manifold 43, the seal cap 219, the rotating mechanism 104, the load lock chamber 110, etc.).

(b) With the present embodiment, the film formation inhibiting gas (e.g., a HCL gas) is supplied from the second gas supply unit to the boat insulation portion 34 when performing the film forming step. This makes it possible to prevent the film-forming gases and the reaction products from adhering to the boat insulation portion 34. In other words, even if the temperature of the sidewall of the boat insulation portion 34 is lower than the film-forming temperature (e.g., 1500 to 1800 degrees Celsius), it is possible to effectively restrain the film-forming gases and the reaction products from adhering to the surface of the boat insulation portion 34 and to reduce the amount of particles generated within the processing chamber 44.

The film formation inhibiting gas supplied from the second gas supply unit is diffused to not only the boat insulation portion 34 but also the surface of the inductively heated body 48 surrounding the boat insulation portion 34 and the inner wall of the processing chamber 44. With the present embodiment, it is therefore possible to effectively restrain the film-forming gases from adhering to not only the sidewall of the boat insulation portion 34 but also the inductively heated body 48 surrounding the boat insulation portion 34.

Since the adhesion of the film-forming gases to the surface of the boat insulation portion 34 can be effectively restrained by supplying the film formation inhibiting gas as stated above, the boat insulation portion 34 may be actively cooled when performing the film forming step. More specifically, it may be possible to supply the film formation inhibiting gas and the second cooling gas to the surface of the boat insulation portion 34 or to supply a specified cooling gas (a heat exchange gas) to the inside of the boat insulation portion 34. By doing so, it becomes possible to further enhance the thermal insulation effect provided by the boat insulation portion 34 and to further reduce the thermal damage to the constituent members positioned below the processing furnace 40.

(c) With the present embodiment, the first cooling gas (e.g., a H₂ gas) is supplied from the first gas supply unit to the wafers 14 when performing the temperature reducing step. This makes it possible to accelerate the cooling of the wafers 14 and to enhance the substrate processing productivity. If the H₂ gas having an increased heat exchange rate is used as the first cooling gas, it is possible to reduce the temperature of the film-formed wafers 14 more rapidly. It is also possible to decrease the flow rate of the first cooling gas and to reduce damage to the SiC films formed on the wafers 14.

(d) With the present embodiment, the second cooling gas (e.g., a H₂ gas) is supplied from the second gas supply unit to the boat insulation portion 34 when supplying the first cooling gas to the wafers 14 in the temperature reducing step. Therefore, even if the first cooling gas grown hot by the heat exchange with the wafers 14 flows along the sidewall of the boat insulation portion 34, it is possible to effectively prevent the temperature from rising in the boat insulation portion 34. As a result, it is possible to shorten the time required for the temperature reducing step and to enhance the substrate processing productivity. If the H₂ gas having an increased heat exchange rate is used as the second cooling gas, it is possible to effectively prevent the temperature from rising in the boat insulation portion 34. It is also possible to decrease the flow rate of the second cooling gas and to restrain the separation of the adhering materials from the surface of the boat insulation portion 34 or the diffusion of the particles.

(e) With the present embodiment, the fifth cooling gas (e.g., an Ar gas) is supplied from the third gas supply unit into the load lock chamber 110 when performing the unloading step. The flow rate of the Ar gas as the fifth cooling gas is set to be greater than the flow rate of the Ar gas as the purge gas supplied from the third gas supply unit for the loading step through the temperature reducing step. This makes it possible to further accelerate the cooling of the wafers 14 in the unloading step.

(f) With the present embodiment, after finishing the unloading step and closing the throat shutter 219a, the flow rate of the Ar gas as the fifth cooling gas supplied into the load lock chamber 110 is set to be greater than the flow rate thereof in the unloading step. This makes it possible to further accelerate the cooling of the unloaded wafers 14.

(g) With the present embodiment, the flow rate of the Ar gas supplied from the third gas supply unit into the processing chamber 44 in the loading step and the unloading step is set to be greater than the flow rate of the Ar gas as the fifth cooling gas supplied into the load lock chamber 110. This makes it possible to generate a gas stream flowing from the inside of the processing chamber 44 toward the load lock chamber 110 in the loading step and the unloading step and to prevent the particles from diffusing into the processing chamber 44 from the inside of the load lock chamber 110.

### Second Embodiment

In the first embodiment described above, the nozzle 90 of the second gas supply unit is formed into a rod-like shape. However, the present disclosure is not limited to the first embodiment.

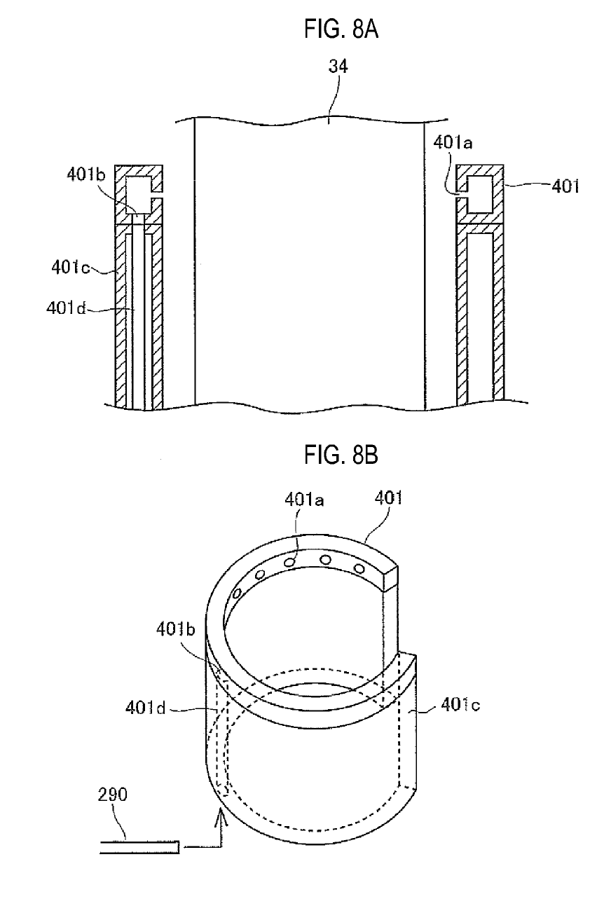

FIG. 8A is a side sectional view showing a nozzle 401 of a second gas supply unit according to a second embodiment of the present disclosure, and FIG. 8B is a perspective view thereof. As shown in FIGS. 8A and 8B, the nozzle 401 of the second gas supply unit according to the present embodiment is formed into an annular shape to surround the upper extension of the boat insulation portion 34. In other words, the nozzle 401 is formed into a C-like hollow cylindrical cross-sectional shape to surround only the upper extension of the boat insulation portion 34.

The nozzle 401 is supported by a heat exchange portion 401c from below. The heat exchange portion 401c is formed into a C-like hollow cylindrical cross-sectional shape just like the nozzle 401. An inert gas, e.g., a N₂ gas or an Ar gas, as a specified cooling gas (heat exchange gas) is supplied into the hollow space of the heat exchange portion 401c. One or more gas inlet holes 401b are formed in, e.g., the bottom portion of the nozzle 401. A downstream end of a gas inlet path 401d through which to supply a film formation inhibiting gas, a second cooling gas, a fourth cooling gas and a purge gas into the nozzle 401 is connected to the gas inlet holes 401b. The gas inlet path 401d is defined within the heat exchange portion 401c. A downstream end of the gas supply pipe 290 described above is connected to an upstream end of the gas inlet path 401d. One or more gas supply holes 401a through which to horizontally supply the gases toward the upper side surface of the boat insulation portion 34 are formed on an inner circumferential wall of the nozzle 401. The gas supply holes 401a are arranged in some embodiments at a regular interval in a circumferential direction.

With this configuration, it is possible to cause the film formation inhibiting gas and other gases to uniformly flow along the circumferential direction of the boat insulation portion 34. It is also possible to narrow the downward flow path of various kinds of gases supplied from the first gas supply unit to the wafers 14. In other words, it is possible to reliably bring the hot gases into contact with the side surface of the boat insulation portion 34 and an inner circumferential wall of the heat exchange portion 401c. This makes it possible to facilitate heat exchange of the boat insulation portion 34 and the heat exchange portion 401c with the hot gases, to efficiently cool the hot gases and to reduce thermal damage to the constituent members positioned below the processing furnace 40. If the inner circumferential wall of the heat exchange portion 401c is cooled by supplying an inert gas such as a N₂ gas or an Ar gas into the heat exchange portion 401c, it is possible to further accelerate the heat exchange between the hot gases and the heat exchange portion 401c and to reduce the thermal damage in a more reliable manner.

If the film formation inhibiting gas is supplied toward only the upper extension of the boat insulation portion 34 as in the present embodiment, it is possible to effectively restrain damage of the boat insulation portion 34. In other words, the film formation inhibiting gas flows toward a lower side of the boat insulation portion 34. In a hypothetical case where the film formation inhibiting gas is supplied from the upper extension and a lower extension of the boat insulation portion 34 at a uniform flow rate, the film formation inhibiting gas supplied from the upper extension of the boat insulation portion 34 is merged with the film formation inhibiting gas supplied from the lower extension of the boat insulation portion 34. Thus, the lower extension of the boat insulation portion 34 is exposed to a large amount of the film formation inhibiting gas and is damaged. In the present embodiment, however, the film formation inhibiting gas is supplied from only the upper extension of the boat insulation portion 34. This makes it possible to avoid the problem noted above.

In the present embodiment, description has been made of the case where the nozzle 401 and the heat exchange portion 401c are formed into a C-like hollow cylindrical shape. However, the present disclosure is not limited to the present embodiment. In other words, the circumferential end portions of the C-like nozzle 401 may be joined together so that the nozzle 401 can have a ring-shaped cross section. This makes it possible to make uniform the gas supply flow rate and the cross-sectional area of the flow path over the entire circumferential region of the boat insulation portion 34. It is also possible to make uniform the cooling efficiency of the boat insulation portion 34 and the film formation inhibiting effect.

### Third Embodiment

In the second embodiment described above, the nozzle 401 of the second gas supply unit is formed into an annular shape to surround the upper extension of the boat insulation portion 34. However, the present disclosure is not limited to the second embodiment.

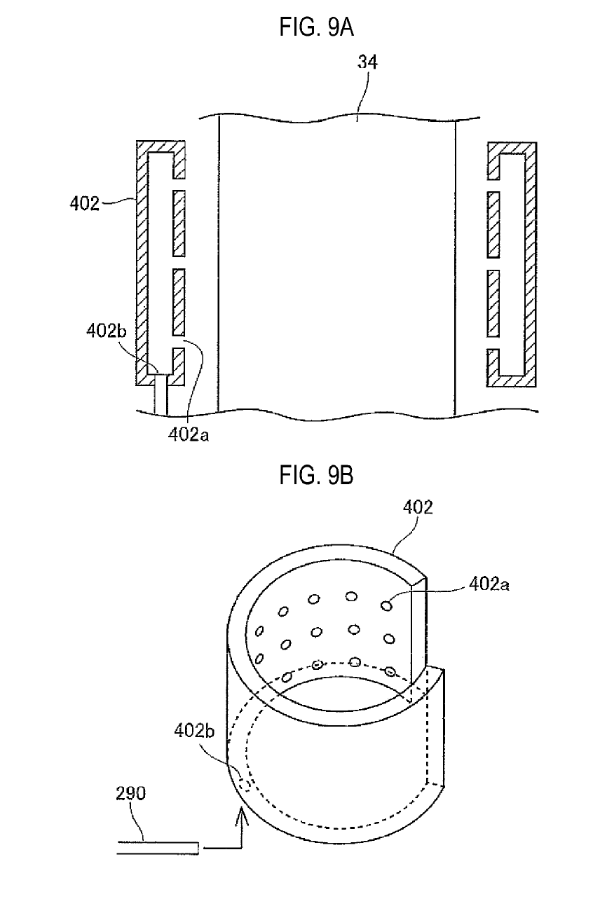

FIG. 9A is a side sectional view showing a nozzle 402 of a second gas supply unit according to a third embodiment of the present disclosure, and FIG. 9B is a perspective view thereof. As shown in FIGS. 9A and 9B, the nozzle 402 of the second gas supply unit according to the present embodiment is formed into an annular tubular shape to surround a vertical entire region of the boat insulation portion 34. In other words, the nozzle 402 is formed into a C-like hollow cylindrical cross-sectional shape to surround a broad region of the boat insulation portion 34 in a circumferential direction and a vertical direction. One or more gas supply holes 402a through which to horizontally supply the gases toward the entire side region of the boat insulation portion 34 are formed on an inner circumferential wall of the nozzle 402. The gas supply holes 402a are arranged preferably in some embodiments at a regular interval in the circumferential direction and at a specified interval in the vertical direction. A gas inlet hole 402b is defined in, e.g., a bottom portion of the nozzle 402. A downstream end of the gas supply pipe 290 through which to supply a film formation inhibiting gas, a second cooling gas, a fourth cooling gas and a purge gas into the nozzle 402 is connected to the gas inlet holes 402b.

With this configuration, it is possible to cause the film formation inhibiting gas and other gases to uniformly flow over the circumferential direction of the boat insulation portion 34. It is also possible to narrow a downward flow path of various kinds of gases supplied from the first gas supply unit to the wafers 14. In other words, it is possible to reliably bring the hot gases into contact with the side surface of the boat insulation portion 34 and the inner circumferential wall of the nozzle 402. This makes it possible to facilitate heat exchange of the boat insulation portion 34 and the nozzle 402 with the hot gases, to efficiently cool the hot gases and to reduce thermal damage to the constituent members positioned below the processing furnace 40. In particular, if the inner circumferential wall of the nozzle 402 is cooled by supplying a second cooling gas or a fourth cooling gas into the nozzle 402, it is possible to further accelerate the heat exchange between the hot gases and the nozzle 402 and to reduce the thermal damage in a more reliable manner.

In the present embodiment, a diameter of the gas supply holes 402a may be changed so that the flow rate of the film formation inhibiting gas supplied to the upper extension of the boat insulation portion 34 can be smaller than the flow rate of the film formation inhibiting gas supplied to a lower extension of the boat insulation portion 34. This makes it possible to effectively restrain damage of the boat insulation portion 34 even when the film formation inhibiting gas supplied from the upper extension of the boat insulation portion 34 is merged with the film formation inhibiting gas supplied from the lower extension of the boat insulation portion 34.

In the present embodiment, description has been made where the nozzle 402 is formed into a C-like hollow cylindrical shape. However, the present disclosure is not limited to the present embodiment. In other words, the circumferential end portions of the C-like nozzle 402 may be joined together so that the nozzle 402 can have a ring-shaped cross section. This makes it possible to make uniform the gas supply flow rate and the cross-sectional area of the flow path over the entire circumferential region of the boat insulation portion 34. It is also possible to make uniform the cooling efficiency of the boat insulation portion 34 and the film formation inhibiting effect.

### Other Embodiments

While certain embodiments of the present disclosure have been specifically described above, the present disclosure is not limited to these embodiments but may be modified in many different forms without departing from the scope and spirit of the disclosure.

As an example, not only the film formation inhibiting gas but also the second cooling gas may be supplied from the second gas supply unit in the film forming step of the present disclosure. Since the supply of the film formation inhibiting gas can effectively restrain the film-forming gases from adhering to the surface of the boat insulation portion 34, it is possible to actively cool the boat insulation portion 34 when performing the film forming step (Despite the cooling, it is possible to effectively restrain the adhesion of the film-forming gases to the boat insulation portion 34). As a result, it is possible to further enhance the thermal insulation effect provided by the boat insulation portion 34 and to further reduce the thermal damage to the constituent members positioned below the processing furnace 40.

As an additional example, the temperature reducing step according to the present disclosure is not limited to the case where the supply of the first cooling gas from the first gas supply unit and the supply of the second cooling gas from the second gas supply unit are started at the same time. For example, in the temperature reducing step, the supply of the H₂ gas from only the second gas supply unit may be started at first and the temperature of the boat 30 and the wafers 14 may be reduced to, e.g., about 1200 degrees Celsius, by the heat transfer through the boat insulation portion 34. Thereafter, the supply of the H₂ gas from the first gas supply unit may be started. This makes it possible to prevent sudden cooling of the boat 30 and the wafers 14 from the just-after-processing temperature (1500 to 1800 degrees Celsius) and to reduce damage to the boat 30 and the wafers 14 which may be caused by thermal stress.

As an additional example, instead of the H₂ gas, a rare gas, such as an Ar gas or the like, or a N₂ gas may be used as the first cooling gas and the second cooling gas according to the present disclosure. If the H₂ gas having an increased heat exchange rate is used as the first cooling gas and the second cooling gas, it is possible to increase the temperature reducing efficiency stated above and to reduce the flow rate of the first cooling gas and the second cooling gas. In the case where other gases having a heat exchange rate lower than that of the H₂ gas are used as the first cooling gas and the second cooling gas, it is possible to prevent sudden reduction of the temperature of the SiC films, the wafers 14, the boat 30 and the boat insulation portion 34 and to reduce damage of the SiC films, the wafers 14, the boat 30 and the boat insulation portion 34. The kinds of first cooling gas and second cooling gas may be changed during the course of supplying the first cooling gas and the second cooling gas. For example, an inert gas such as an Ar gas may be used in an early stage of the temperature reducing step. After the temperature is reduced to a specified temperature, the Ar gas may be replaced by a H₂ gas. It is preferred in some embodiments that the H₂ gas be replaced by the Ar gas before unloading the boat 30 to thereby reduce the H₂ concentration within the processing chamber 44.

As an additional example, instead of the Ar gas, it may be possible to use a rare gas, such as a helium (He) gas, a neon (Ne) gas, a krypton (Kr) gas or a Xenon (Xe) gas, or a N₂ gas as the third cooling gas, the fourth cooling gas and the fifth cooling gas.

As an additional example, instead of the hydrogen chloride (HCL) gas illustrated above, other halogen gases such as a chlorine (Cl₂) gas and the like may be used as the film formation inhibiting gas.

As an additional example, instead of the silane (SiH₄) gas illustrated above, a disilane (Si₂H₆) gas or a trisilane (Si₃H₈) gas may be used as the silicon-containing gas. In addition, a gas containing silicon and chlorine, e.g., a tetrachlorosilane (SiCl₄) gas, a trichlorosilane (SiHCl₃, commonly called “TCS”) gas or a dichlorosilane (SiH₂Cl₂, commonly called “DCS”) may be used as the silicon-containing gas.

As an additional example, instead of the propane (C₃H₈) gas illustrated above, other carbon-containing gases such as an ethylene (C₂H₄) gas, an acetylene (C₂H₂) gas and the like may be used as the carbon-containing gas.

In the foregoing embodiments, description has been made in the case where the present disclosure is applied to a SiC epitaxial growth apparatus. However, the present disclosure is not limited to the foregoing embodiments. It goes without saying that the present disclosure can be applied to all kinds of substrate processing apparatuses for heating the inside of a processing chamber and processing substrates. Moreover, the heating method is not limited to the induction heating method illustrated in the foregoing embodiments. For example, other heating methods such as a resistor heating method and a lamp irradiation heating method may be employed in the present disclosure. However, the present disclosure can provide remarkable effects when applied to a substrate processing apparatus for heating the inside of processing chamber to an ultra-high temperature. The present disclosure can provide particularly remarkable effects when applied to a substrate processing apparatus employing an induction heating method.

Hereinafter, aspects of the present disclosure will be additionally stated.

A first aspect of the present disclosure may provide a substrate processing apparatus, including: a processing chamber configured to process a plurality of substrates; a substrate holder accommodated within the processing chamber and configured to hold the substrates in a vertically spaced-apart relationship; a thermal insulation portion configured to support the substrate holder from below within the processing chamber; a heating unit provided to surround a substrate accommodating region within the processing chamber; and a second gas supply unit configured to supply a specified gas to at least a thermal insulation portion accommodating region within the processing chamber.

The substrate processing apparatus according to the first aspect may further include a first gas supply unit configured to supply a film-forming gas to the substrate accommodating region within the processing chamber.

A second aspect of the present disclosure may provide a substrate processing apparatus, including: a processing chamber configured to process a plurality of substrates; a substrate holder accommodated within the processing chamber and configured to hold the substrates in a vertically spaced-apart relationship; a thermal insulation portion configured to support the substrate holder from below within the processing chamber; a heating unit provided to surround a substrate accommodating region within the processing chamber; a first gas supply unit configured to supply at least a film-forming gas to the substrate accommodating region within the processing chamber; a second gas supply unit configured to supply at least a cooling gas to a thermal insulation portion accommodating region within the processing chamber; and a control unit configured to control at least the heating unit, the first gas supply unit and the second gas supply unit, the control unit configured to: form specified thin films on the substrates by causing the heating unit to start a heating operation, elevating a temperature of the substrates to a specified temperature and causing the first gas supply unit to start supply of the film-forming gas; and then reduce the temperature of the substrates by stopping the heating operation performed by the heating unit and the supply of the film-forming gas from the first gas supply unit and causing the second gas supply unit to start supply of the cooling gas.

A third aspect of the present disclosure may provide a substrate processing apparatus, including: a processing chamber configured to process a plurality of substrates; a substrate holder accommodated within the processing chamber and configured to hold the substrates in a vertically spaced-apart relationship; a thermal insulation portion configured to support the substrate holder from below within the processing chamber; a heating unit provided to surround a substrate accommodating region within the processing chamber; a first gas supply unit configured to supply a film-forming gas to the substrate accommodating region within the processing chamber; a second gas supply unit configured to supply at least a film formation inhibiting gas to a thermal insulation portion accommodating region within the processing chamber; and a control unit configured to control at least the heating unit, the first gas supply unit and the second gas supply unit, the control unit configured to form specified thin films on the substrates by causing the heating unit to start a heating operation, elevating a temperature of the substrates to a specified temperature and causing the first gas supply unit to start supply of the film-forming gas, the control unit configured to cause the second gas supply unit to supply the film formation inhibiting gas when forming the thin films.

The first gas supply unit may include one or more first nozzles provided in a region between the heating unit and the substrate holder. One or more gas supply holes through which to horizontally supply the film-forming gas toward one side of the substrate accommodating region within the processing chamber may be formed in the side portions of the first nozzles.

The second gas supply unit may include one or more second nozzles provided in a region between the heating unit and the thermal insulation portion. One or more gas supply holes through which to horizontally supply the specified gas toward one side of the thermal insulation portion may be formed in the side portions of the second nozzles.

The second gas supply unit may include a second nozzle of annular shape provided in a region between the heating unit and the thermal insulation portion to surround an upper extension of the thermal insulation portion. One or more gas supply holes through which to horizontally supply the specified gas toward an upper side surface of the thermal insulation portion may be formed in an inner circumferential wall of the second nozzle.

The second gas supply unit may include a second nozzle of annular tubular shape provided in a region between the heating unit and the thermal insulation portion to surround a vertical entire region of the thermal insulation portion. One or more gas supply holes through which to horizontally supply the specified gas toward an entire side region of the thermal insulation portion may be formed in an inner circumferential wall of the second nozzle.

A fourth aspect of the present disclosure may provide a substrate processing apparatus, including: a processing chamber configured to process a plurality of substrates; a substrate holder accommodated within the processing chamber and configured to hold the substrates in a vertically spaced-apart relationship; a thermal insulation portion configured to support the substrate holder from below within the processing chamber; a heating unit provided to surround a substrate accommodating region within the processing chamber; a preparatory chamber configured to accommodate the substrate holder unloaded from the processing chamber; a first gas supply unit configured to supply a film-forming gas, a first cooling gas and a third cooling gas to the substrate accommodating region within the processing chamber; a second gas supply unit configured to supply a film formation inhibiting gas, a second cooling gas and a fourth cooling gas to the thermal insulation portion accommodating region within the processing chamber; a third gas supply unit configured to supply a fifth cooling gas to a substrate accommodating region within the preparatory chamber; and a control unit configured to control at least the heating unit, the first gas supply unit, the second gas supply unit and the third gas supply unit, the control unit configured to sequentially perform: a process of forming specified thin films on the substrates by causing the heating unit to start a heating operation, elevating a temperature of the substrates to a specified temperature and causing the first gas supply unit to start supply of the film-forming gas; a process of reducing the temperature of the substrates to a specified unloading temperature by stopping the heating operation performed by the heating unit and the supply of the film-forming gas performed by the first gas supply unit, starting the supply of the first cooling gas performed by the first gas supply unit and the supply of the second cooling gas performed by the second gas supply unit, and purging the preparatory chamber by causing the third gas supply unit to start supply of the fifth cooling gas at a first flow rate; and a process of starting the supply of the third cooling gas performed by the first gas supply unit and the supply of the fourth cooling gas performed by the second gas supply unit after the temperature of the substrates is reduced to the unloading temperature, causing the third gas supply unit to start supply of the fifth cooling gas at a second flow rate greater than the first flow rate, and unloading the substrate holder from the processing chamber into the preparatory chamber.

The control unit may be configured to, when unloading the substrate holder from the inside of the processing chamber into the preparatory chamber, set the flow rate of the fifth cooling gas supplied from the third gas supply unit greater than the total flow rate of the third cooling gas supplied from the first gas supply unit and the fourth cooling gas supplied from the second gas supply unit.

The control unit may be configured to perform a process of further reducing the temperature of the substrates by causing the third gas supply unit to start supply of the fifth cooling gas at a third flow rate greater than the second flow rate after finishing the unloading of the substrate holder into the preparatory chamber and hermetically sealing the inside of the processing chamber.

The film formation inhibiting gas may preferably be a gas containing chlorine.

The first cooling gas and the second cooling gas may be a gas containing hydrogen.

The third cooling gas, the fourth cooling gas and the fifth cooling gas may be an inert gas.

A fifth aspect of the present disclosure may provide a semiconductor device manufacturing method, including: accommodating a substrate holder and a thermal insulation portion within a processing chamber, the substrate holder configured to hold a plurality of substrates in a vertically spaced-apart relationship, the thermal insulation portion configured to support the substrate holder from below within the processing chamber; forming specified thin films on the substrates by causing a heating unit provided to surround a substrate accommodating region within the processing chamber to start a heating operation, elevating a temperature of the substrates to a specified temperature and causing a first gas supply unit to start supply of a film-forming gas to the substrate accommodating region within the processing chamber; and reducing the temperature of the substrates by stopping the heating operation performed by the heating unit and the supply of the film-forming gas performed by the first gas supply unit and causing a second gas supply unit to start supply of a cooling gas to a thermal insulation portion accommodating region within the processing chamber.

A sixth aspect of the present disclosure may provide a semiconductor device manufacturing method, including: accommodating a substrate holder and a thermal insulation portion within a processing chamber, the substrate holder configured to hold a plurality of substrates in a vertically spaced-apart relationship, the thermal insulation portion configured to support the substrate holder from below within the processing chamber; and forming specified thin films on the substrates by causing a heating unit provided to surround a substrate accommodating region within the processing chamber to start a heating operation, elevating a temperature of the substrates to a specified temperature and causing a first gas supply unit to start supply of a film-forming gas to the substrate accommodating region within the processing chamber, wherein a film formation inhibiting gas is supplied from a second gas supply unit to a thermal insulation portion accommodating region within the processing chamber when forming the thin films.

A seventh aspect of the present disclosure may provide a semiconductor device manufacturing method, including: accommodating a substrate holder and a thermal insulation portion within a processing chamber, the substrate holder configured to hold a plurality of substrates in a vertically spaced-apart relationship, the thermal insulation portion configured to support the substrate holder from below within the processing chamber; forming specified thin films on the substrates by causing a heating unit provided to surround a substrate accommodating region within the processing chamber to start a heating operation, elevating a temperature of the substrates to a specified temperature and causing a first gas supply unit to start supply of a film-forming gas to the substrate accommodating region within the processing chamber; reducing the temperature of the substrates to a specified unloading temperature by stopping the heating operation performed by the heating unit and the supply of the film-forming gas performed by the first gas supply unit, starting the supply of the first cooling gas performed by the first gas supply unit and the supply of the second cooling gas to the thermal insulation portion accommodating region within the processing chamber performed by the second gas supply unit, and purging the preparatory chamber by causing the third gas supply unit to start supply of the fifth cooling gas into the preparatory chamber accommodating the substrate holder unloaded from the processing chamber at a first flow rate; starting the supply of the third cooling gas performed by the first gas supply unit and the supply of the fourth cooling gas performed by the second gas supply unit after the temperature of the substrates is reduced to the unloading temperature, causing the third gas supply unit to continuously supply the fifth cooling gas at a second flow rate greater than the first flow rate, and unloading the substrate holder from the processing chamber into the preparatory chamber; and further reducing the temperature of the substrates by causing the third gas supply unit to continuously supply the fifth cooling gas at a third flow rate greater than the second flow rate after finishing the unloading of the substrate holder into the preparatory chamber and hermetically sealing the inside of the processing chamber.

With the substrate processing apparatus and the semiconductor device manufacturing method according to the present disclosure, it is possible in some embodiments to enhance the substrate processing productivity by accelerating heat dissipation when reducing the temperature of the substrates and to increase the substrate processing quality by restraining the generation of foreign materials within the processing chamber during the film forming step.

While certain embodiments have been described, these embodiments have been presented by way of example only, and are not intended to limit the scope of the disclosures. Indeed, the novel apparatuses and methods described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a processing chamber configured to process a plurality of substrates;
a substrate holder accommodated within the processing chamber and configured to hold the substrates in a vertically spaced-apart relationship;
a thermal insulation portion configured to support the substrate holder from below within the processing chamber;
a heating unit surrounding a substrate accommodating region within the processing chamber; and
a gas supply system configured to supply a specified gas to at least a thermal insulation portion accommodating region within the processing chamber.

2. A substrate processing apparatus, comprising:
a processing chamber configured to process a plurality of substrates;
a substrate holder accommodated within the processing chamber and configured to hold the substrates in a vertically spaced-apart relationship;
a thermal insulation portion configured to support the substrate holder from below within the processing chamber;
a heating unit surrounding a substrate accommodating region within the processing chamber;
a first gas supply unit configured to supply at least a film-forming gas to the substrate accommodating region within the processing chamber;
a second gas supply unit configured to supply at least a cooling gas to a thermal insulation portion accommodating region within the processing chamber; and
a control unit configured to control at least the heating unit, the first gas supply unit and the second gas supply unit, the control unit configured to: form specified thin films on the substrates by causing the heating unit to start a heating operation, elevating a temperature of the substrates to a specified temperature and causing the first gas supply unit to start supply of the film-forming gas; and then reduce the temperature of the substrates by stopping the heating operation performed by the heating unit and the supply of the film-forming gas from the first gas supply unit and causing the second gas supply unit to start supply of the cooling gas.

3. The substrate processing apparatus of claim 2, wherein the first gas supply unit includes one or more first nozzles provided in a region between the heating unit and the substrate holder, and one or more gas supply holes provided in side portions of the first nozzles through which the film-forming gas is horizontally supplied toward one side of the substrate accommodating region within the processing chamber.

4. The substrate processing apparatus of claim 2, wherein the second gas supply unit includes one or more second nozzles provided in a region between the heating unit and the thermal insulation portion, and one or more gas supply holes provided in side portions of the second nozzles through which the cooling gas is horizontally supplied toward one side of the thermal insulation portion.

5. The substrate processing apparatus of claim 2, wherein the second gas supply unit includes a second nozzle of annular shape provided in a region between the heating unit and the thermal insulation portion to surround an upper extension of the thermal insulation portion, and one or more gas supply holes provided in an inner circumferential wall of the second nozzle through which the cooling gas is horizontally supplied toward an upper side surface of the thermal insulation portion.

6. The substrate processing apparatus of claim 2, wherein the second gas supply unit includes a second nozzle of annular tubular shape provided in a region between the heating unit and the thermal insulation portion to surround a vertical entire region of the thermal insulation portion, and one or more gas supply holes provided in an inner circumferential wall of the second nozzle through which the cooling gas is horizontally supplied toward an entire side region of the thermal insulation portion.

7. A substrate processing apparatus, comprising:
a processing chamber configured to process a plurality of substrates;
a substrate holder accommodated within the processing chamber and configured to hold the substrates in a vertically spaced-apart relationship;
a thermal insulation portion configured to support the substrate holder from below within the processing chamber;
a heating unit surrounding a substrate accommodating region within the processing chamber;
a first gas supply unit configured to supply a film-forming gas to the substrate accommodating region within the processing chamber;
a second gas supply unit configured to supply at least a film formation inhibiting gas to a thermal insulation portion accommodating region within the processing chamber; and
a control unit configured to control at least the heating unit, the first gas supply unit and the second gas supply unit, the control unit configured to form specified thin films on the substrates by causing the heating unit to start a heating operation, elevating a temperature of the substrates to a specified temperature and causing the first gas supply unit to start supply of the film-forming gas, the control unit configured to cause the second gas supply unit to supply the film formation inhibiting gas when forming the thin films.

8. A semiconductor device manufacturing method, comprising:
accommodating a substrate holder and a thermal insulation portion within a processing chamber, the substrate holder configured to hold a plurality of substrates in a vertically spaced-apart relationship, the thermal insulation portion configured to support the substrate holder from below within the processing chamber;
forming specified thin films on the substrates by causing a heating unit provided to surround a substrate accommodating region within the processing chamber to start a heating operation, elevating a temperature of the substrates to a specified temperature and causing a first gas supply unit to start supply of a film-forming gas to the substrate accommodating region within the processing chamber; and
reducing the temperature of the substrates by stopping the heating operation performed by the heating unit and the supply of the film-forming gas performed by the first gas supply unit and causing a second gas supply unit to start supply of a cooling gas to a thermal insulation portion accommodating region within the processing chamber.

9. A semiconductor device manufacturing method, comprising:
accommodating a substrate holder and a thermal insulation portion within a processing chamber, the substrate holder configured to hold a plurality of substrates in a vertically spaced-apart relationship, the thermal insulation portion configured to support the substrate holder from below within the processing chamber; and
forming specified thin films on the substrates by causing a heating unit provided to surround a substrate accommodating region within the processing chamber to start a heating operation, elevating a temperature of the substrates to a specified temperature and causing a first gas supply unit to start supply of a film-forming gas to the substrate accommodating region within the processing chamber, wherein a film formation inhibiting gas is supplied from a second gas supply unit to a thermal insulation portion accommodating region within the processing chamber when forming the thin films.

10. A substrate processing method, comprising:
accommodating a substrate holder and a thermal insulation portion within a processing chamber, the substrate holder configured to hold a plurality of substrates in a vertically spaced-apart relationship, the thermal insulation portion configured to support the substrate holder from below within the processing chamber; and
forming specified thin films on the substrates by causing a heating unit provided to surround a substrate accommodating region within the processing chamber to start a heating operation, elevating a temperature of the substrates to a specified temperature and causing a first gas supply unit to start supply of a film-forming gas to the substrate accommodating region within the processing chamber, wherein a film formation inhibiting gas is supplied from a second gas supply unit to a thermal insulation portion accommodating region within the processing chamber when forming the thin films.
